(19) United States
(12) Patent Application Publication
(10) Pub. No.: US 2007/0263266 A1
(43) Pub. Date: Nov. 15, 2007

(54) Method and System for Annotating Photographs During a Slide Show

(76) Inventors: Nadav Har'el, Haifa (IL); Shila Ofek-Koifman, Haifa (IL)

Correspondence Address: IBM CORPORATION, T.J. WATSON RESEARCH CENTER, P.O. BOX 218, YORKTOWN HEIGHTS, NY, 10598, US

(21) Appl. No.: 11/382,277

(22) Filed: May 9, 2006

(51) Int. Cl. G03F 3/10; H04N 1/23

(52) U.S. Cl. 358/527; 358/302

(57) ABSTRACT

The present invention relates to a method and system for annotating photographs during a slide show. The method comprises displaying the at least one photograph during the slide show and recording a voice-description corresponding to the slide show. Further, the method comprises transcribing the voice-description to form at least one transcribed-text corresponding to each photograph. The at least one transcribed-text is then stored in a database. Also, the present invention enables a user to conduct a search over the photographs in the slide show using annotations such as the transcribed-text or the voice-description.

### FIELD OF THE INVENTION

The present invention relates to annotating photographs and more specifically, to a method and a system for associating annotations to photographs during a slide show and enabling a photograph search using the annotations.

### BACKGROUND OF THE INVENTION

In recent years, digital cameras have been replacing film cameras. A growing number of users are storing their photographs on computers. A number of software programs are available to manage these photographs.

Existing software programs enable users to organize and manage photographs into photo albums. The photographs in the photo albums can then be labeled with appropriate descriptions. Some of the existing methods of labeling photographs comprise annotating the photographs with text descriptions or with voice tags. These voice tags can then be transcribed and indexed.

Japanese patent No. 2003087624, titled, “Digital Camera” assigned to Matsushita Electric Ind Co Ltd, discloses a method for annotating images with speech, and indexing the transcribed speech.

Another method as described in U.S. Pat. No. 6,084,582, titled “Method and apparatus for recording a voice narration to accompany a slide show”, records a voice-description to accompany a slide show presentation. Further, the recorded voice-descriptions can be segmented such that segments of voice-descriptions can be digitized, stored and associated with each slide in the slide show.

There exist systems that enable photograph search in a photo album. Some of these systems employ ‘Automatic Image Annotation’ techniques and search based on keywords. Also, cameras often annotate photograph with the time the photograph was taken, and sometimes also the location of the photograph. These time and location annotations can also be used to conduct search. However, the kind of queries that can be answered using these automatic annotations is very limited.

Additionally, in some of the existing systems, users can record short voice segments in which they describe each photograph. These voice segments can then be transcribed using automatic transcription software and the resulting text can then be used for searching the photographs. For example, various modern digital cameras come with a voice annotation feature, with which users can record a short voice segment and attach the voice segment with a specific picture. Some photo-management systems can transcribe these annotations and conduct a search on them. Other photo-management systems, for example AT&T's Shoebox, let users record photograph description after downloading the photographs to their computers, and these descriptions can be transcribed and made searchable.

However, annotating each photograph individually is an inconvenient job for a user and as the collection of photographs gets bigger it takes long time to annotate the photographs. Further, searching using voice annotations such as time, location and names of people facilitates only limited kinds of queries.

### SUMMARY OF THE INVENTION

An object of the present invention is to provide a method and a system for associating annotations to photographs during a slide show and enabling a photograph search using the annotations.

In order to fulfill the above object, the method comprises displaying at least one photograph during the slide show. In response to displaying at least one photograph, a voice-description corresponding to the slide show is recorded. Thereafter, the voice-description is transcribed to form at least one transcribed-text corresponding to each photograph.

Further, the voice-description corresponding to the slide show can be filtered to remove periods of silence or noise. The voice-description can then be segmented on the basis of a photograph being displayed in the slide show to form a segmented-voice-description corresponding to the photograph. The segmented-voice-description can be saved in a compressed format and can be associated to its corresponding photograph.

The system includes a displaying module for displaying photographs during a slide show and a recording module for recording a voice-description for each photograph. The system further includes a transcribing module for transcribing a voice-description for each photograph and a storing module for storing a transcribed-text for each photograph.

The system further includes a searching module, the searching module searches a photograph based on keywords, and the photographs found as a result of the search are displayed in a search-display module in an order of a context score corresponding to each photograph.

### BRIEF DESCRIPTION OF THE DRAWINGS

The foregoing objects and advantages of the present invention for a method for annotating photographs during a slide show may be more readily understood by one skilled in the art with reference being had to the following detailed description of several preferred embodiments thereof, taken in conjunction with the accompanying drawings wherein like elements are designated by identical reference numerals throughout the several views, and in which:

FIG. 1 illustrates a flow diagram of a method for associating at least one annotation to at least one photograph during a slide show in accordance with an embodiment of the present invention.

FIG. 2 illustrates a flow diagram of a method for recording a voice-description corresponding to a slide show in accordance with an embodiment of the present invention.

FIG. 3 illustrates a flow diagram of a method for making photographs in a slide show searchable in accordance with an embodiment of the present invention.

FIG. 4 illustrates a flow diagram of a method for associating contextual information with a photograph in the slide show in accordance with an embodiment of the present invention.

FIG. 5 illustrates a block diagram of a system for associating at least one annotation to at least one photograph during a slide show in accordance with an embodiment of the present invention.

FIG. 6 illustrates a block diagram of a recording module for recording a voice-description during a slide show in accordance with an embodiment of the present invention.

### DETAILED DESCRIPTION

Before describing in detail embodiments that are in accordance with the present invention, it should be observed that the embodiments reside primarily in combinations of method steps and system components related to annotating photographs during a slide show. Accordingly, the system components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein. Thus, it will be appreciated that for simplicity and clarity of illustration, common and well-understood elements that are useful or necessary in a commercially feasible embodiment may not be depicted in order to facilitate a less obstructed view of these various embodiments.

In this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or system that comprises, has, includes, contains a list of elements does not include only those elements but may include other elements not expressly listed or inherent to such process, method, article, or system. An element preceded by “comprises . . . a”, “has . . . a”, “includes . . . a”, “contains . . . a” does not, without more constraints, preclude the existence of additional identical elements in the process, method, article, or system that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

It will be appreciated that embodiments of the present invention described herein may be comprised of one or more conventional processors and unique stored program instructions that control the one or more processors to implement, in conjunction with certain non-processor circuits, some, most, or all of the functions of the method and system for annotating photographs during a slide show described herein. The non-processor circuits may include, but are not limited to, a transceiver, signal drivers, clock circuits and power source circuits. As such, these functions may be interpreted as steps of a method to annotate photographs during a slide show described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

Generally speaking, pursuant to the various embodiments, the present invention relates to associating annotations to photographs during a slide show. The annotations can comprise voice-descriptions and corresponding text descriptions. The photographs can be made searchable using these voice-descriptions or text descriptions. Those skilled in the art will realize that the above recognized advantages and other advantages described herein are merely exemplary and are not meant to be a complete rendering of all of the advantages of the various embodiments of the present invention.

A user often shows computerized photo albums to others, such as family and friends, generally accompanied with a verbal description of the photographs. A slide show mode is typically used to display photographs one after another, magnified to fill an entire screen. The present invention proposes a method and a system that enables the user to record verbal description during such slide show sessions to display the photographs. The verbal description can then be segmented such that the segments of the verbal description are associated as annotations with corresponding photographs in the slide show.

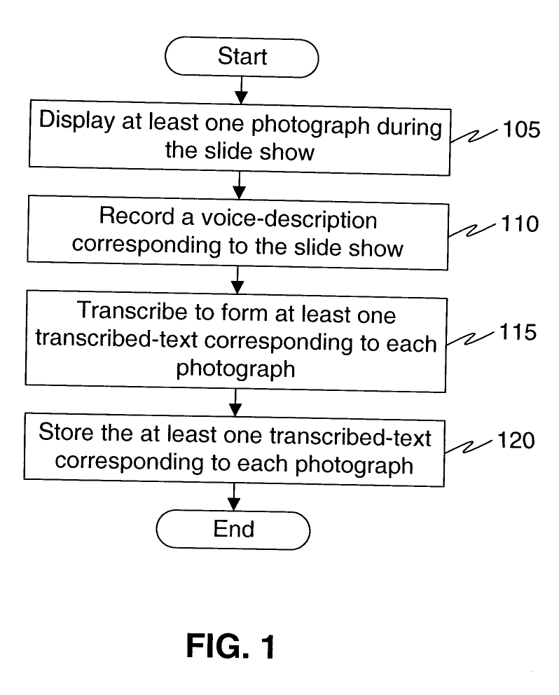

Referring now to the drawings, and in particular FIG. 1, a flow diagram of a method for associating at least one annotation to at least one photograph during a slide show is shown in accordance with an embodiment of the present invention. Those skilled in the art, however, will recognize and appreciate that the specifics of this illustrative example are not specifics of the present invention itself and that the teachings set forth herein are applicable in a variety of alternative settings. For example, since the teachings described herein do not depend on the number of photographs in the slide show or the number of annotations for each photograph, they can be applied to any number of photographs in the slide show or any number annotations for each photograph. As such, other alternative implementations of using different types of annotations, such as voice or text, for any number of photographs in a slide show are contemplated and are within the scope of the various teachings described.

Referring back to FIG. 1, after initiating a slide show on a display device, such as a personal computer, a personal digital assistant or a mobile phone, at least one photograph is displayed at step 105. The slide show can comprise any number of slides, as permitted by the memory space and the processor capability of the display device. During the slide show, while providing description corresponding to the photographs, the user can record a voice-description corresponding to the slide show at step 110. In an embodiment of the present invention, the slide show and the operation of recording the voice-description can be initiated simultaneously. For example, the slide show and the operation of recording can be started at the click of a button. Thereafter, the voice-description can be segmented corresponding to the photographs being displayed during the slide show to form a segmented-voice-description. For example, a personal computer on which a slide show is being displayed can determine which photograph is displayed on a given time stamp. As a result, the personal computer can determine which part of the continuous voice-description applies to which photograph based on the time stamp. The segmented-voice-description can then be transcribed to form at least one transcribed-text corresponding to each photograph at step 115. The segmented-voice-description can be transcribed using an automatic transcription software. The at least one transcribed-text corresponding to each photograph can be stored in the personal device at step 120. In an embodiment of the present invention, the segmented-voice-description is stored in compressed form along with the corresponding transcribed-text. Therefore enabling a user to conduct a search for the photographs based on the segmented-voice-description and corresponding transcribed-text information. Moreover, the segmented-voice-description can be played again when the user browses the same slide show or the same photographs. Further, the slide shows along with the corresponding voice-descriptions can be shared with others.

In an embodiment of the present invention, a user can annotate the same slide show more than one time. For example, a user can show the user's wedding photographs to the user's family and during the slide show a segmented-voice-description and corresponding transcribed-text can be stored. Further, the user can then show the same slide show to the user's friends and thereby another segmented-voice-description and corresponding transcribed-text is acquired. The different segmented-voice-description and the corresponding transcribed-text acquired during different time stamps are managed and stored while omitting any repetition that might be there. Therefore, enabling a user to update a transcribed text associated with a photograph is updated each time a user displays the photograph on the slide show. Further, this enable in improved searching capability for the photographs as the transcribed-text covers the various descriptions that were given during the more than one slide show.

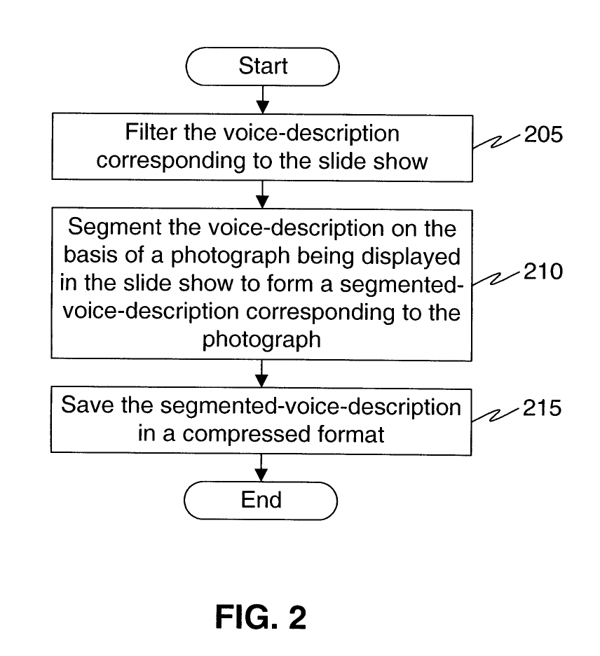

Turning now to FIG. 2, a flow diagram of a method for recording a voice-description corresponding to a slide show is shown in accordance with an embodiment of the present invention. In an embodiment of the present invention, when the slide show is initiated, recording of the voice-description can also be started simultaneously. During the slide show there can be periods of silence when a user is not describing anything about the photograph. For example, if a user is showing a slide show of the user's wedding photographs to the user's friends, there can be periods of silence when the user wishes not to describe some photographs. Similarly, there can be periods of unwanted noise during the slide show, for example when people around the display device are talking at the same time. Therefore, while recording the voice-description, the voice-description can be filtered corresponding to the slide show at step 205. The filtering step comprises ignoring periods of silence or noise during the slide show. Upon filtering the voice-description, the voice-description is segmented on the basis of a photograph being displayed in the slide show to form a segmented-voice-description corresponding to the photograph at step 210. There can be a segmented-voice-description corresponding to each photograph in the slide show. The segmented-voice-descriptions can be saved in a compressed format at step 215. Saving the segmented-voice-descriptions in compressed format enables conserving the resources.

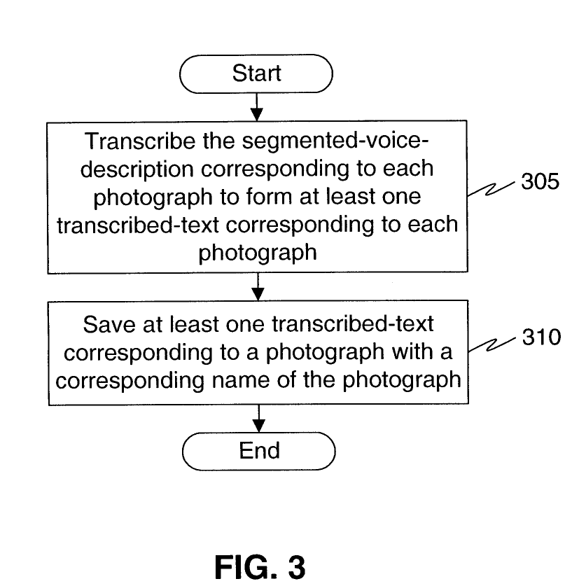

Turning now to FIG. 3, a flow diagram of a method for making photographs in a slide show searchable is shown in accordance with an embodiment of the present invention. Segmented-voice-descriptions corresponding to photographs in a slide show are obtained and stored in a compressed format using the method shown in FIG. 2. As there can be more than one transcribed-text corresponding to each photograph, the segmented-voice-descriptions is transcribed to form at least one transcribed-text corresponding to each photograph at step 305. In an exemplary embodiment of the present invention, a transcribed-text can be a segmented-voice-description translated into text and stored as text file. A user can search for a particular photograph using the information related to the segmented-voice-description and the corresponding transcribed-text as keywords. As a result of the search, a set of photographs are displayed which are related to the information submitted by the user. At step 310, a transcribed-text corresponding to a photograph is saved with a name same as the corresponding name of the photograph. In an embodiment of the present invention, more than one transcribed-text corresponding to a photograph can be saved. For example, if a user views a slide show more than one time, different transcribe-texts can be generated each time corresponding to a photograph. Therefore, there can be more than one transcribed-text associated with each photograph. In an embodiment of the present invention, deleting repeated text and adding new text can refine the transcribed-text associated with a photograph in the slide show. This enables a user to use a broader list of keywords for searching each photograph.

In another embodiment of the present invention, the transcribed-text corresponding to a photograph can be embedded in the photograph in a predefined form. The predefined form can be, for example, a Joint Photography Experts Group comment (JPEG comment) or an Exchangeable Image File header (EXIF header). Transcribed-text embedded in the photographs can make it convenient for the user to see the transcribed-text along with the photographs during the slide show.

In yet another embodiment of the present invention, a database is maintained that stores a reference to a photograph and a transcribed-text corresponding to the photograph. A reference is an unique identification information of a photograph. The unique identification information can be a unique file checksum corresponding to a photograph. When a photograph is access during a slide show using the reference the corresponding transcribed-text is retrieved and is displayed to the user. Further, when a search is conducted using information related to the transcribed-text certain, the database is searched for the corresponding transcribed-text and using the corresponding reference a photograph corresponding to the transcribed-text can be retrieved.

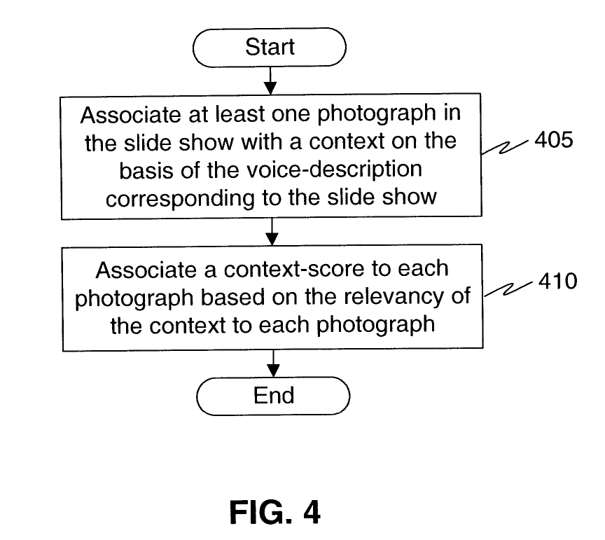

Referring now to FIG. 4, a flow diagram of a method for associating contextual information with a photograph in the slide show in accordance with an embodiment of the present invention. The photographs in the slide show can be associated with a context on the basis of the voice-description corresponding to the slide show at step 405. The context can be circumstantial information pertaining to the photographs in the slide show. For example, a user's slide show can comprise photographs of a pleasure trip and photographs of a party during the pleasure trip. If the user wishes to display only the photographs of the party, the contextual information associated with the photograph can be used to display only the photographs related to the party. In an embodiment, the photographs are searched based on the contextual information. Moreover, the photographs having similar time stamps can also be associated with similar context. Therefore, each photograph having similar context are displayed together. Further, at step 410, a context-score can be associated to each photograph based on the relevancy of the context to each photograph. The context-score can assist in getting a better estimate of the relevancy of the context to a corresponding photograph during a search result. In an exemplary embodiment of the present invention, the photographs are sorted and displayed on the basis of their corresponding context-score.

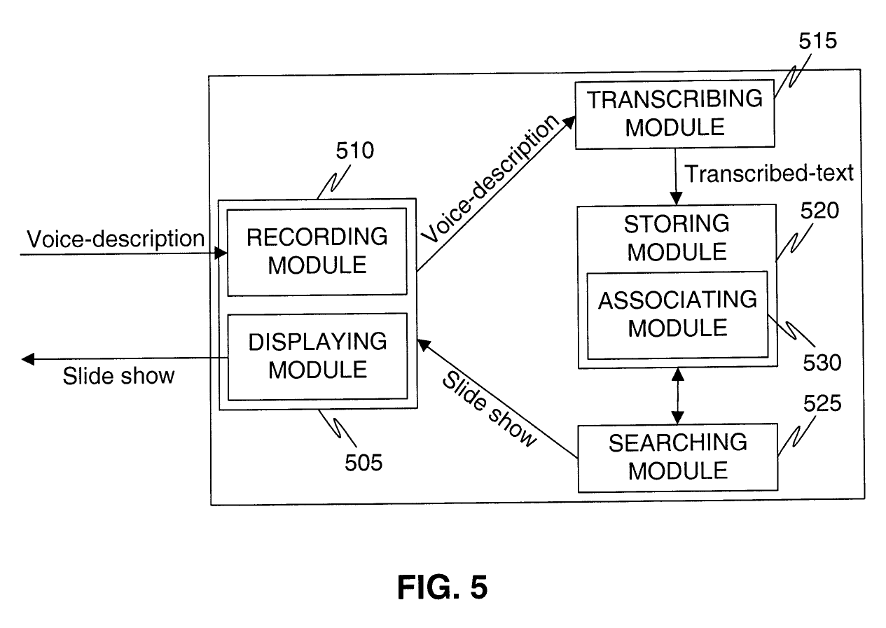

Referring now to FIG. 5, a block diagram of a system for associating at least one annotation to at least one photograph during a slide show is shown in accordance with an embodiment of the present invention. Those skilled in the art will realize that the system can be deployed on a device displaying the slide show as a computer program, for example on a personal computer, a personal digital assistant or a mobile phone. As mentioned earlier, the annotation can be a voice-description or a transcribed-text and there can be more than one annotations associated with each photograph in a slide show. The system comprises a displaying module 505, a recording module 510, a transcribing module 515, a storing module 520 and a searching module 525.

Displaying module 505 is configured for displaying the slide show. The slide show can be displayed on a computer screen, a television screen, a personal digital assistant screen or a mobile phone screen. Photographs in the slide show can be displayed one after the other in a predefined interval, magnified to fill an entire screen for displaying.

Recording module 510 is configured for recording a voice-description given by a user corresponding to the slide show. In an embodiment of the present invention, when the user starts displaying the slide show, the system automatically initiates recording module 510 and the voice-description corresponding to the slide show can be recorded without user intervention. The user can give the voice-description by speaking into a microphone or a headset attached to the device displaying the slide show and recording module 510. Recording module 510 can take the voice-description as an input and forward it to transcribing module 515. Transcribing module 515 is configured to transcribe the voice-description into a corresponding transcribed-text. In an embodiment of the present invention, the voice-description is segmented to form segmented-voice-description. A segmented-voice-description can be associated with each photograph in the slide show. Essentially, a segmented-voice-description corresponding to a photograph can be a brief description of the photograph. As mentioned earlier, a segmented-voice-description may not exist for some photographs in case of a period of silence or noise during the slide show. The segmented-voice-descriptions can then be transcribed by transcribing module 515 to obtain a transcribed-text corresponding to each photograph in the slide show. However, if there is no segmented-voice-description associated with some photographs in the slide show, transcribed-text may not exist for those photographs.

The transcribed-text obtained from transcribing module 515 can be forwarded to storing module 520. Storing module 520 is configured to store the transcribed-text corresponding to each photograph. In an embodiment of the present invention, a transcribed-text corresponding to a photograph is saved with a name same as the corresponding name of the photograph. In an embodiment of the present invention, more than one transcribed-text corresponding to a photograph can be saved. For example, if a user views a slide show more than one time, different transcribe-text can be generated each time corresponding to a photograph. Therefore, there can be more than one transcribed-text associated with each photograph. In an embodiment of the present invention, deleting repeated text and adding new text can refine the transcribed-text associated with a photograph in the slide show. This enables a user to use a broader list of keywords for searching each photograph.

In yet another embodiment of the present invention, a database is maintained that stores a reference to a photograph and a transcribed-text corresponding to the photograph. A reference is an unique identification information of a photograph. The unique identification information can be a unique file checksum corresponding to a photograph. When a photograph is access during a slide show using the reference the corresponding transcribed-text is retrieved and is displayed to the user. Further, when a search is conducted using information related to the transcribed-text certain, the database is searched for the corresponding transcribed-text and using the corresponding reference a photograph corresponding to the transcribed-text can be retrieved.

One embodiment of the present invention deploys the method described in FIG. 4. In accordance with this embodiment, storing module 520 further comprises an associating module 530. Associating module 530 can associate at least one photograph in the slide show with a context on the basis of the voice-description corresponding to the voice-description. The context can be a circumstantial information pertaining to the at least one photograph in the slide show. Associating module 530 can further be configured for associating a context-score to each photograph based on the relevancy of the context to each photograph. A user can use the information related to at least one of a transcribed-text, a segmented-voice-description and a context to search for a photograph.

Searching module 525 can search a photograph based on at least one keyword given by the user. The at least one keyword can relate to at least one annotation, for example transcribed-text, corresponding to the photograph that the user wishes to display. In an embodiment of the present invention, searching module 525 further comprises a search-display module coupled to displaying module 505 and searching module 525. The search-display module can be configured to display the search results in an order of the context-score corresponding to each photograph.

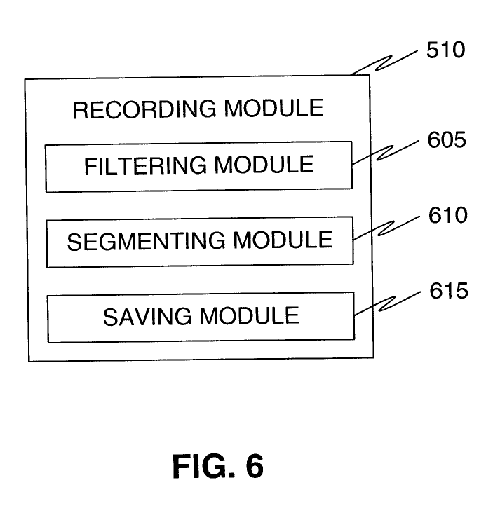

Turning now to FIG. 6, a block diagram of recording module 510 for recording a voice-description during a slide show is shown in accordance with an embodiment of the present invention. Recoding module 510 comprises a filtering module 605, a segmenting module 610, and a saving module 615. Filtering module 601 is configured to filter the voice-description corresponding to the slide show. Upon filtering the voice-description, the periods of silence and noise can be filtered out and ignored while recording. Further, segmenting module 610 segments the filtered voice-description to obtain segmented-voice-description corresponding to the photographs. Therefore, each photograph in the slide show can have an associated segmented-voice-description describing the photograph. The segmented-voice-descriptions can be saved in a compressed form, for example in ZIP format, using saving module 615.

Various embodiment of the present invention provides system and method for annotating photographs during a slide show. The system simultaneously associate a voice-description based on the description provided by the user during the slide show. Therefore, saving the user from an extra effort of annotating the photographs with the voice-description. Further, the various embodiments of the present invention associate a plurality of transcribed-text, a context and context-score with each photograph. Therefore, enabling an efficient way of searching the photographs.

The method for annotating photographs during a slide show, as described in the invention or any of its components may be embodied in the form of a computing device. The computing device can be, for example, but not limited to, a general-purpose computer, a programmed microprocessor, a micro-controller, a peripheral integrated circuit element, and other devices or arrangements of devices, which are capable of implementing the steps that constitute the method of the invention.

The computing device executes a set of instructions that are stored in one or more storage elements, in order to process input data. The storage elements may also hold data or other information as desired. The storage element may be in the form of a database or a physical memory element present in the processing machine.

The set of instructions may include various instructions that instruct the computing device to perform specific tasks such as the steps that constitute the method of the invention. The set of instructions may be in the form of a program or software. The software may be in various forms such as system software or application software. Further, the software might be in the form of a collection of separate programs, a program module with a larger program or a portion of a program module. The software might also include modular programming in the form of object-oriented programming. The processing of input data by the computing device may be in response to user commands, or in response to results of previous processing or in response to a request made by another computing device.

In the foregoing specification, specific embodiments of the present invention have been described. However, one of ordinary skills in the art appreciates that various modifications and changes can be made without departing from departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims.

What is claimed is:

1. A method for associating at least one annotation to at least one photograph during a slide show, the method comprising:
displaying the at least one photograph during the slide show;
recording a voice-description corresponding to the slide show;
transcribing to form at least one transcribed-text corresponding to each photograph; and
storing the at least one transcribed-text corresponding to each photograph.

2. The method of claim 1, wherein the step of recording comprises:
filtering the voice-description corresponding to the slide show;
segmenting the voice-description on the basis of a photograph being displayed in the slide show to form a segmented-voice-description corresponding to the photograph; and
saving the segmented-voice-description in a compressed format.

3. The method of claim 2, wherein the step of filtering comprises ignoring at least one of a period of silence and noise during the slide show.

4. The method of claim 1, wherein the step of transcribing comprises transcribing the segmented-voice-description corresponding to each photograph to form at least one transcribed-text corresponding to each photograph.

5. The method of claim 1, wherein the step of storing comprises saving at least one transcribed-text corresponding to a photograph with a corresponding name of the photograph.

6. The method of claim 1, wherein the step of storing comprises embedding at least one transcribed-text corresponding to a photograph in the photograph in a predefined form.

7. The method of claim 6, wherein the predefined form can be one of a Joint Photography Experts Group comment (JPEG comment) and Exchangeable Image File header (EXIF header).

8. The method of claim 1, wherein the step of storing comprises associating a reference to a photograph with a corresponding at least one transcribed-text, wherein each transcribed-text is stored in a database and the reference refers to a unique identification information of the corresponding photograph.

9. The method of claim 8, wherein the unique identification information is a unique file checksum corresponding to a photograph.

10. The method of claim 1, wherein the step of storing further comprising associating the at least one photograph in the slide show with a context on the basis of the voice-description corresponding to the slide show, wherein the context is a circumstantial information pertaining to the at least one photograph in the slide show.

11. The method of claim 10 further comprising associating a context-score to each photograph based on the relevancy of the context to each photograph.

12. A system for associating at least one annotation to at least one photograph during a slide show, the system comprises:
a displaying module, the displaying module displaying the at least one photograph during the slide show;
a recording module, the recording module recording a voice-description corresponding to the slide show;
a transcribing module, the transcribing module transcribing to form at least one transcribed-text corresponding to each photograph; and
a storing module, the storing module storing the at least one transcribed-text corresponding to each photograph.

13. The system of claim 12, wherein the recording module comprises:
a filtering module, the filtering module filtering the voice-description corresponding to the slide show;
a segmenting module, the segmenting module segmenting the voice-description on the basis of a photograph being displayed in the slide show to form a segmented-voice-description corresponding to the photograph; and
a saving module, the saving module saving the segmented-voice-description in a compressed format.

14. The system of claim 12, wherein the storing module further comprising an associating module, the associating module associating the at least one photograph in the slide show with a context on the basis of the voice-description corresponding to the slide show, wherein the context is a circumstantial information pertaining to the at least one photograph in the slide show.

15. The system of claim 14, wherein the associating module further comprising associating a context-score to each photograph based on the relevancy of the context to each photograph.

16. The system of claim 12 further comprising a searching module, the searching module searching a photograph based on at least one keyword, wherein the at least one keyword relates to the at least one annotation corresponding to the photograph.

17. The system of claim 12, further comprising a search-display module, wherein the search-display module displays the search results in an order of the context-score corresponding to each photograph.

18. A computer program product comprising a computer usable medium having a computer readable program for associating at least one annotation to at least one photograph during a slide show, wherein the computer readable program when executed on a computer causes the computer to:
display the at least one photograph during the slide show;
record a voice-description corresponding to the slide show;
transcribe to form at least one transcribed-text corresponding to each photograph; and
store the at least one transcribing-text corresponding to each photograph.
